(19) United States
(12) Patent Application Publication
(10) Pub. No.: US 2016/0076141 A1
(43) Pub. Date: Mar. 17, 2016

(54) MANUFACTURING METHOD OF HARD SLIDING MEMBER

(71) Applicant: Kabushiki Kaisha Kobe Seiko Sho (Kobe Steel, Ltd.), Kobe-shi (JP)

(72) Inventor: Satoshi HIROTA, Takasago-shi (JP)

(73) Assignee: Kabushiki Kaisha Kobe Seiko Sho (Kobe Steel, Ltd.), Kobe-shi (JP)

(21) Appl. No.: 14/816,349

(22) Filed: Aug. 3, 2015

(30) Foreign Application Priority Data
Sep. 12, 2014 (JP) 2014-186108

(51) Int. Cl. C23C 14/48; C23C 14/02; C23C 14/06

(52) U.S. Cl. CPC C23C 14/48; C23C 14/0605; C23C 14/022; C23C 14/025

(57) ABSTRACT

A manufacturing method of a hard sliding member of the present invention includes a surface treatment step of surface-treating a surface of a substrate, and a carbon film formation step of forming a carbon film on the surface of the substrate by performing arc ion plating with using a target containing carbon. In the carbon film formation step, formation of the carbon film is started by performing the arc ion plating while introducing a hydrocarbon gas, then an introduction amount of the hydrocarbon gas is reduced and the arc ion plating is continued so as to form an intermediate layer, and a surface layer made of ta-C is formed on a surface.

### BACKGROUND OF THE INVENTION

1. Field of the Invention

The present invention relates to a manufacturing method of a hard sliding member.

2. Description of the Related Art

Conventionally, there is a known technique of, in order to improve hardness of a hard sliding member such as engine parts of a piston, a cylinder, and the like, forming a hard carbon film on a surface of a substrate of the member.

For example, JP 2014-122415 A discloses a technique of forming a film made of diamond-like carbon (DLC) having higher hardness than that of a substrate of a hard sliding member on a surface of the substrate as a hard carbon film by a chemical vapor deposition method (CVD) or the like. This DLC film has much higher hardness than hardness of the substrate and internal stress is also high. Thus, there is a problem that in a case where the DLC film is formed directly on the surface of the substrate, a hardness difference thereof, that is, an internal stress difference is increased, and an adhesion property of both the film and the substrate is lowered. This related art discloses that by placing an intermediate layer between the DLC film and the substrate, the intermediate layer being made of tungsten carbide (WC) having intermediate hardness, the adhesion property of the DLC film is improved.

In recent years, use of a ta-C film having further higher hardness than that of the DLC film as a hard carbon film is desired. The ta-C film has a structure mainly composed of a sp3 bond of carbon atoms, and has remarkably high hardness in comparison to the DLC film mainly composed of a sp2 bond.

Regarding this ta-C film, it is known that by performing film deposition by ion plating, that is, arc ion plating (hereinafter, referred to as the AIP), hardness is remarkably increased in comparison to film deposition by other film deposition methods (such as sputtering). The AIP is a film deposition method of melting and evaporating part of a target material by arc discharge and attaching the part onto a surface of a work.

However, since the ta-C film formed by the AIP has remarkably high hardness, even by placing the intermediate layer made of WC between the ta-C film and the substrate, the adhesion property is not easily improved.

### SUMMARY OF THE INVENTION

The present invention is achieved in order to solve the above problem, and an object thereof is to provide a manufacturing method of a hard sliding member capable of suppressing a hard carbon film containing ta-C from separating from a substrate.

As a result of much research in order to solve the above problem, the present inventor found that in a case where a hard carbon film containing ta-C is formed in a chamber by AIP, and when a hydrocarbon gas is introduced into the chamber, a hydrogen atom (H) contained in the hydrocarbon gas enters a bond between carbon atoms (between C—C) to form not a sp3 bond which is original for ta-C but a C—H—C bond, and as a result, hardness of a film to be generated is lowered and a hardness difference between the carbon film and a surface of a substrate (that is, a stress difference) is reduced, so that an adhesion property can be improved.

The present inventor controlled internal stress and hardness of the carbon film so that the hardness of the carbon film to be formed becomes low on the surface of the substrate and the hardness becomes higher where the carbon film is more distant from the substrate by forming the carbon film by the AIP while reducing a supply amount of the hydrocarbon gas, and thereby, reached a method of forming the carbon film on the surface of the substrate with a favorable adhesion property while ensuring the hardness of the carbon film containing ta-C.

The present invention is achieved in such a way, and is to provide a manufacturing method of a hard sliding member including a substrate, and a carbon film formed on a surface of the substrate, the carbon film having higher hardness than hardness of the substrate. This method includes a surface treatment step of surface-treating the surface of the substrate, and a carbon film formation step of forming the carbon film on the surface of the substrate by performing AIP in a chamber with using a target containing carbon, and in the carbon film formation step, formation of the carbon film is started by performing the AIP while introducing a hydrocarbon gas into the chamber, and then an introduction amount of the hydrocarbon gas is reduced and the AIP is continued, so that ta-C is formed at least on a surface.

With this method, the hard carbon film containing ta-C is formed by the AIP, and by bonding hydrogen to carbon in the carbon film by introduction of the hydrocarbon gas in an initial stage of the AIP, the hardness of the carbon film is lowered, so that a hardness difference between the carbon film and the substrate can be reduced. When the hardness difference is reduced in such a way, separation of the hard carbon film containing ta-C from the substrate can be prevented. By reducing the hydrocarbon gas during formation of the carbon film, the carbon film containing hard ta-C can be obtained at least on the surface at the end. That is, a hydrogen content of the carbon film becomes lower where the carbon film is more distant from the substrate, and a part which is the most distant from the substrate contains hard ta-C. As a result, while the hard carbon film containing ta-C is formed on the surface, separation of this carbon film from the substrate can be prevented.

Preferably, the carbon film formation step includes a step of performing the AIP with using the target containing carbon while introducing the hydrocarbon gas into the chamber in such a manner that the introduction amount of the hydrocarbon gas into the chamber is gradually reduced over time.

When the introduction amount of the hydrocarbon gas is gradually reduced in such a way, the hardness of the carbon film can be gradually increased in accordance with progress of the formation of the carbon film. Thereby, separation of the carbon film can be further prevented.

Preferably, the carbon film formation step includes a step of forming a surface layer containing ta-C by continuing the AIP with using the target containing carbon even after stopping introduction of the hydrocarbon gas.

With this method, the hard surface layer containing ta-C of desired thickness can be formed.

Preferably, the hydrocarbon gas is acethylene (C₂H₂). When acethylene is used as the hydrocarbon gas, acethylene is readily available and easily handled. Furthermore, since a hydrogen component embrittles a coating and invites embrittlement, as a less hydrogen component as possible may be contained, and as much carbon as possible may be contained from a viewpoint of a deposition rate. Thus, acethylene which meets these conditions the best is preferably selected.

The hydrocarbon gas may be methane (CH₄). In this case, methane is readily available and easily handled as well.

Preferably, the surface treatment step includes a step of forming an underlying layer on the substrate by the AIP.

With this method, the underlying layer and the carbon film can be continuously formed by an AIP process, so that the adhesion property is more improved.

Preferably, the carbon film formation step is started while introducing the hydrocarbon gas immediately before an end of the step of forming the underlying layer.

By starting the carbon film formation step while introducing the hydrocarbon gas immediately before the end of the step of generating the underlying layer in such a way, an internal stress difference in a border part between the underlying layer and the carbon film is more reduced (in other words, more uniformized). Thereby, an adhesion property of the underlying layer and the carbon film is more improved.

Preferably, the surface treatment step further includes an interposition layer formation step of forming an interposition layer having higher hardness than that of the underlying layer and lower hardness than that of the carbon film on the underlying layer by the AIP.

With existence of the interposition layer, stress between the carbon film and the underlying layer can be further eased. Furthermore, the underlying layer, the interposition layer, and the carbon film can be continuously formed by the AIP process, so that the adhesion property is improved.

Preferably, the surface treatment step is a step of treating the surface of the substrate by metal bombardment.

With such a characteristic, by reforming the surface of the substrate itself by the metal bombardment, the adhesion property with the carbon film can be improved. Furthermore, there is a low likelihood that the surface of the substrate treated by the metal bombardment separates from the substrate like the underlying layer.

As described above, with the manufacturing method of the hard sliding member of the present invention, separation of the hard carbon film containing ta-C from the substrate can be prevented.

### BRIEF DESCRIPTION OF THE DRAWINGS

FIG. 1 is an enlarged sectional view showing an embodiment of a hard sliding member manufactured by a manufacturing method of a hard sliding member of the present invention.

FIG. 2 is a plan view showing a basic configuration of a film deposition device used in the manufacturing method of the hard sliding member of the present invention.

FIG. 3 is a flowchart showing a procedure of the manufacturing method of the hard sliding member of the present invention.

FIG. 4 is a diagram showing a result of a hardness test of a hard sliding member according to the embodiment of the present invention.

FIG. 5 is a diagram showing a result of a hardness test of a hard sliding member according to a comparative example of the present invention.

FIG. 6 is a diagram showing a result of a hardness test of a hard sliding member according to another comparative example of the present invention.

FIG. 7 is an enlarged sectional view of a hard sliding member having an interposition layer between an underlying layer and a carbon film manufactured by a manufacturing method of a hard sliding member according to another embodiment of the present invention.

### DESCRIPTION OF THE PREFERRED EMBODIMENTS

Hereinafter, an embodiment of the present invention will be described further in detail with reference to the drawings.

FIG. 1 shows a hard sliding member 20 to be manufactured by this embodiment (such as engine parts of a piston, a cylinder, and the like, or cutting tools). In a manufacturing method of this hard sliding member 20, specifically, after surface-treating a substrate 21 (such as formation of an underlying layer 22), a carbon film 23 having higher hardness than that of the substrate 21 is formed by AIP.

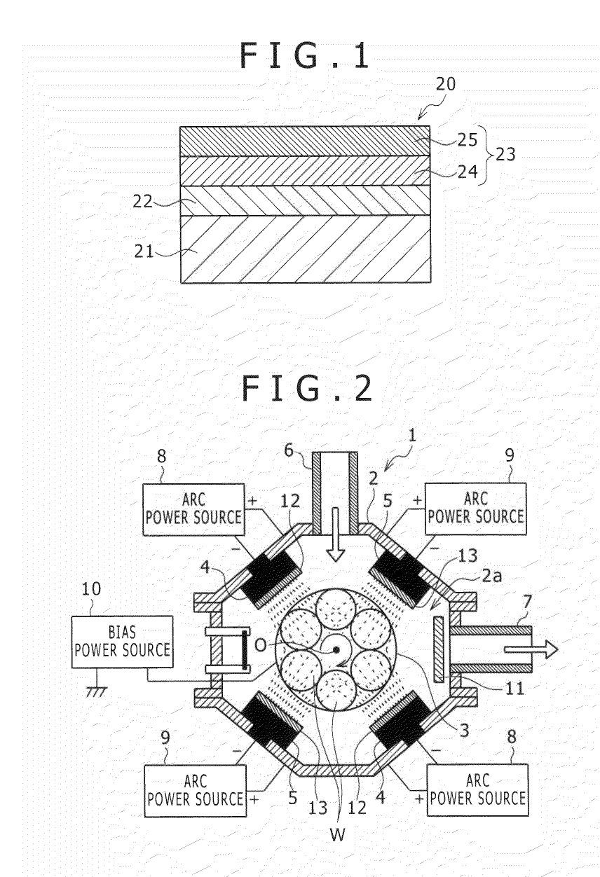

This manufacturing method includes forming the carbon film 23 by the AIP in a chamber such as a chamber 2 of a film deposition device 1 shown in FIG. 2 while introducing a hydrocarbon gas into the chamber 2, and controlling hardness (that is, internal stress) of the carbon film 23 so that the hardness of the carbon film 23 to be formed becomes low on a surface of the substrate 21 and the hardness becomes higher where the carbon film is more distant from the substrate 21 by reducing an introduction amount of the hydrocarbon gas during the AIP. With this method, while ensuring the hardness of the carbon film 23 containing ta-C, an adhesion property of the carbon film 23 to the surface of the substrate 21 can be improved.

Specifically, the manufacturing method of the hard sliding member 20 according to this embodiment is a method of forming the carbon film 23 having higher hardness than that of the substrate 21 on the surface of the substrate 21, including:

a surface treatment step of surface-treating the surface of the substrate 21; and

a carbon film formation step of forming the carbon film 23 on the surface of the substrate 21 by performing the AIP with using targets 12 containing carbon (C).

In the carbon film formation step, formation of the carbon film 23 is started by performing the AIP while introducing the hydrocarbon gas into the chamber 2 of the film deposition device 1 in which the substrate 21 is accommodated, then the introduction amount of the hydrocarbon gas is reduced and the AIP is continued, so that ta-C is formed at least on a surface of the carbon film 23. Specifically, when ta-C is formed, in order to contain as less hydrogen as possible in a sp3 bond of carbon atoms forming ta-C (ideally, in order not to contain any hydrogen), the introduction amount of the hydrocarbon gas inside the chamber 2 is reduced as far as possible (ideally, the introduction amount is zero).

With this manufacturing method, the hard carbon film 23 containing ta-C is formed by the AIP in the chamber 2, and by bonding hydrogen to carbon in the carbon film 23 to be formed by introduction of the hydrocarbon gas into the chamber 2 in an initial stage of the AIP, the hardness is lowered (that is, the internal stress is lowered), so that a hardness difference between the carbon film 23 and the substrate 21 can be reduced. The hardness difference reduced in such a way can prevent the hard carbon film 23 containing ta-C from separating from the substrate 21. By reducing the introduction amount of the hydrocarbon gas in accordance with progress of the formation of the carbon film 23, the carbon film 23 containing hard ta-C can be obtained at least on the surface at the end. As a result, while the hard carbon film 23 containing ta-C is formed, separation of this carbon film 23 from the substrate 21 can be prevented.

Meanwhile, it is thought that a DLC film having higher hardness than that of tungsten carbide used for a conventional intermediate layer is formed by CVD as an intermediate layer placed between the ta-C film and the substrate. However, even in a case where the DLC film formed by the CVD as the intermediate layer placed between the ta-C film and the substrate (hereinafter, referred to as the CVD-DLC film) is used, it is thought that an adhesion property of the ta-C film is not easily improved. This is because in general, a coating structure is largely different between the CVD-DLC film and the ta-C film formed by the AIP, and the films are largely different from a viewpoint of denseness (in other words, density) of coatings. Therefore, even when the CVD-DLC film serving as the intermediate layer for easing the stress is used between the substrate and the ta-C film, a hardness difference (in other words, an internal stress difference) still remains between the CVD-DLC film and the ta-C film. Thus, even when the CVD-DLC film is used as the intermediate layer, the problem that the ta-C film separates from the substrate cannot be solved.

Meanwhile, in the present embodiment, the formation of the carbon film 23 is started by performing the AIP while introducing the hydrocarbon gas into the chamber 2 of the film deposition device 1 in which the substrate 21 is accommodated as shown in FIG. 2, then the introduction amount of the hydrocarbon gas is reduced, and ta-C containing no hydrogen is formed at least on the surface. In this way, while the hard carbon film 23 containing ta-C is formed, a difference between hardness of a part of this carbon film 23 in the vicinity of the surface of the substrate 21 and the hardness of the substrate 21 is reduced, so as to prevent the carbon film 23 from separating from the substrate 21.

As the hydrocarbon gas to be introduced into the chamber 2 in the above carbon film formation step, various gases having a composition containing carbon and hydrogen can be used. For example, acethylene (C₂H₂), methane (CH₄), and the like are used from a viewpoint of easy availability and easily handling. In a case of selecting the hydrocarbon gas, since a hydrogen component embrittles a coating and invites embrittlement, as a less hydrogen content as possible is desirable, and from a viewpoint of a deposition rate as a much carbon content as possible is desirable. Thus, acetylene which is most suitable for those conditions is preferably selected. The hydrocarbon gas may be a gas containing atoms other than carbon and hydrogen atoms such as silicon (Si) atoms. For example, trimethylsilane (C₃H₁₀Si) or the like can be used.

The introduction amount of the hydrocarbon gas may be changed so that the introduction amount is the most at the time of a start of the AIP and the introduction amount is zero at the time of an end of the AIP so as to form ta-C. A specific mode of reduction in the introduction amount from the start to the end can be variously set. For example, the introduction amount of the hydrocarbon gas may be set in such a manner that the hydrocarbon gas is gradually reduced from the start of the AIP and the introduction amount is reduced to be zero at the time of the end or the introduction amount becomes zero before the end.

Specifically, the introduction amount of the hydrocarbon gas can be set in such a manner that the hydrocarbon gas is gradually reduced to be zero from the start of the AIP to a certain time, and after the time, the introduction amount of the hydrocarbon gas maintains zero until the end.

The carbon film formation step in such a case includes:

(a) a step of forming an intermediate layer 24 on the surface of the surface-treated substrate 21 (specifically, on the underlying layer 22) by performing the AIP with using the targets 12 containing carbon while introducing the hydrocarbon gas into the chamber 2 in such a manner that the introduction amount into the chamber 2 is gradually reduced over time; and

(b) a step of forming a surface layer 25 containing ta-C by continuing the AIP with using the targets 12 containing carbon after stopping the introduction of the hydrocarbon gas.

As in the above step (a), when the introduction amount of the hydrocarbon gas is gradually reduced, the hardness of the carbon film can be gradually increased in accordance with the progress of the formation of the carbon film 23. Thereby, separation of the carbon film 23 can be further prevented.

As in the above step (b), the carbon film formation step includes the step of forming the surface layer 25 containing ta-C by continuing the AIP with using the targets 12 containing carbon even after stopping the introduction of the hydrocarbon gas into the chamber 2. Thereby, the hard surface layer 25 containing ta-C of desired thickness can be formed.

Furthermore, both the intermediate layer 24 and the surface layer 25 are formed by performing the AIP with using the targets 12 containing carbon. Thus, in comparison to a case where the intermediate layer is deposited by other film deposition methods such as the CVD, a coating structure becomes alike between the intermediate layer 24 and the surface layer 25, and the layers become alike in terms of denseness or density of coatings. Therefore, a hardness difference and an internal stress difference between the intermediate layer 24 and the surface layer 25 are reduced. As a result, there is a low likelihood that the surface layer 25 separates from the intermediate layer 24.

The above surface treatment step includes a step of forming the underlying layer 22 on the substrate 21 by AIP. Thereby, the underlying layer 22 and the carbon film 23 can be continuously formed by an AIP process, so that the adhesion property is more improved. In the underlying layer formation step, specifically, the underlying layer 22 made of a metal coating is formed by the AIP with a metal material containing chromium or the like as targets. The metal material used as the targets contains metal such as chromium, titanium, nickel, silicon, or tungsten. When the AIP is performed, part of the metal material of the targets is melt and evaporated by arc discharge, and attached to the surface of the substrate 21, so that the underlying layer 22 made of a metal coating of chromium or the like is formed. When a nitrogen gas is introduced into the chamber of the film deposition device at the time of performing the AIP, an underlying layer 22 made of a metal nitride coating of chromium or the like is formed. By performing the AIP with using targets of tungsten and carbon, an underlying layer 22 of tungsten carbide (WC) may be formed.

The AIP in the present invention is a film deposition method of melting and evaporating part of the target material by the arc discharge and attaching the part onto the surface of the substrate. Specific description of a film deposition process by the AIP will be given later.

As shown in FIG. 1, the hard sliding member 20 manufactured by the above manufacturing method includes the substrate 21, and the underlying layer 22 and the carbon film 23 (specifically, the intermediate layer 24 and the surface layer 25) successively and continuously formed on the surface of the substrate by the AIP.

The substrate 21 is manufactured from a material such as an aluminum alloy used for manufacturing engine parts such as a piston, a cylinder, and the like, or tungsten carbide used for manufacturing cutting tools.

The underlying layer 22 is a layer covering the surface of the substrate 21 for surface treatment of the substrate 21. When the underlying layer 22 is placed between the substrate 21 and the carbon film 23, the internal stress difference between both the substrate 21 and the carbon film 23 can be reduced, so that affinity of the substrate 21 for the carbon film 23 is improved. The underlying layer 22 is formed by the AIP with using the metal material such as chromium as the targets as described above. The underlying layer 22 is a layer containing metal such as chromium, nitride of the metal, or the like, for example, a layer made of pure chromium having hardness of about 1,000 Hv.

The carbon film 23 has the intermediate layer 24 and the surface layer 25. The intermediate layer 24 and the surface layer 25 are continuously formed by the AIP with using the material containing carbon as the targets.

The surface layer 25 is a layer forming the outermost layer of the hard sliding member 20 and improving hardness of a surface of the hard sliding member 20. The surface layer 25 is a hard film made of ta-C which is composed of a sp3 bond of carbon atoms (C), the film having hardness of about 8,000 Hv.

The intermediate layer 24 is a layer that reduces a hardness difference between the surface layer 25 and the underlying layer 22. The intermediate layer 24 is a film made of soft DLC containing a structure in which a hydrogen atom (H) contained in the hydrocarbon gas which is introduced into the chamber 2 at a start of the AIP enters a bond between carbon atoms (between C—C) to form a C—H—C bond. The intermediate layer 24 has hardness lower than hardness of the surface layer 25 made of ta-C and higher than hardness of the underlying layer 22 (on average, hardness of about 5,000 Hv).

Since the intermediate layer 24 is generated by the AIP while gradually reducing the introduction amount of the hydrocarbon gas, the intermediate layer 24 has a structure in which a hydrogen content is gradually reduced as distant from the underlying layer 22 in the intermediate layer 24. Therefore, a part of the intermediate layer 24 near the underlying layer 22 has low hardness, and a part near the surface layer 25 has high hardness.

Among the hard sliding member 20 formed as above, the intermediate layer 24 of the carbon film 23 formed by introducing the hydrocarbon gas in the initial stage of the AIP has the hardness lowered by bonding hydrogen to carbon (that is, the internal stress in the intermediate layer 24 is lowered). Therefore, a hardness difference between the surface layer 25 made of ta-C and the substrate 21 can be reduced. As a result, separation of the hard carbon film 23 containing ta-C from the substrate 21 can be prevented. In the intermediate layer 24 of the carbon film 23, the hydrogen content in the carbon film 23 is more reduced where the intermediate layer is more distant from the substrate 21. Further, the most distant part from the substrate 21 of the carbon film 23 (that is, the surface layer 25) contains hard ta-C. As a result, while the hard carbon film 23 containing ta-C is formed, separation of this carbon film 23 from separating from the substrate 21 can be prevented.

Next, with reference to FIG. 2, the specific film deposition process by the AIP for manufacturing the above hard sliding member 20 will be described.

The above hard sliding member 20 is manufactured for example with using the above film deposition device 1 shown in FIG. 2.

This film deposition device 1 is a device of, with the substrate 21 of the hard sliding member 20 as works W, continuously forming the underlying layer 22 and the carbon film 23 on surfaces of the works W by the AIP.

That is, the film deposition device 1 shown in FIG. 2 includes the vacuum chamber 2, a rotation table 3 on which the works W are mounted, a plurality of (two in FIG. 2) first arc evaporation sources 4, and a plurality of (two in FIG. 2) second arc evaporation sources 5.

The vacuum chamber 2 has a space portion 2a in which the rotation table 3 and the works W mounted on the rotation table 3 are accommodated. The space portion 2a is maintained in a vacuum or nearly-vacuum state by a vacuum pump (not shown) during the film deposition process. In the vacuum chamber 2, an introduction portion 6 for introducing a gas required for the film deposition process into the space portion 2a, and a discharge portion 7 for discharging the gas after the film deposition process to an exterior from the space portion 2a are provided.

The rotation table 3 is rotated about a center axis O in a state where the plurality of works W is mounted in the space portion 2a during the film deposition process. It should be noted that the rotation table 3 may further include rotation bases on which the works W are individually mounted so that each of the works W can be rotated independently.

The first arc evaporation sources 4 are evaporation sources for performing the AIP to the works W in order to form the underlying layer 22 made of metal such as chromium. The first arc evaporation sources 4 are for example cathode discharge type AIP evaporation sources. Cathodes of arc power sources 8 are connected to the first arc evaporation sources 4. Although anodes of the arc power sources 8 are connected to for example the vacuum chamber 2, the anodes may be connected to other members. The targets 12 of chromium (Cr) serving as a material to form the underlying layer 22 are attached to the first arc evaporation sources 4.

The second arc evaporation sources 5 are evaporation sources for performing the AIP to the works W in order to form the carbon film 23, that is, the intermediate layer 24 made of soft DLC and the surface layer 25 made of ta-C. The second arc evaporation sources 5 are for example cathode discharge type AIP evaporation sources as well as the first arc evaporation sources 4. Cathodes of arc power sources 9 are connected to the second arc evaporation sources 5, and anodes of the arc power sources 9 are connected to for example the vacuum chamber 2. Targets 13 of a material containing carbon (C) serving as a material to form the intermediate layer 24 and the surface layer 25 are attached to the second arc evaporation sources 5.

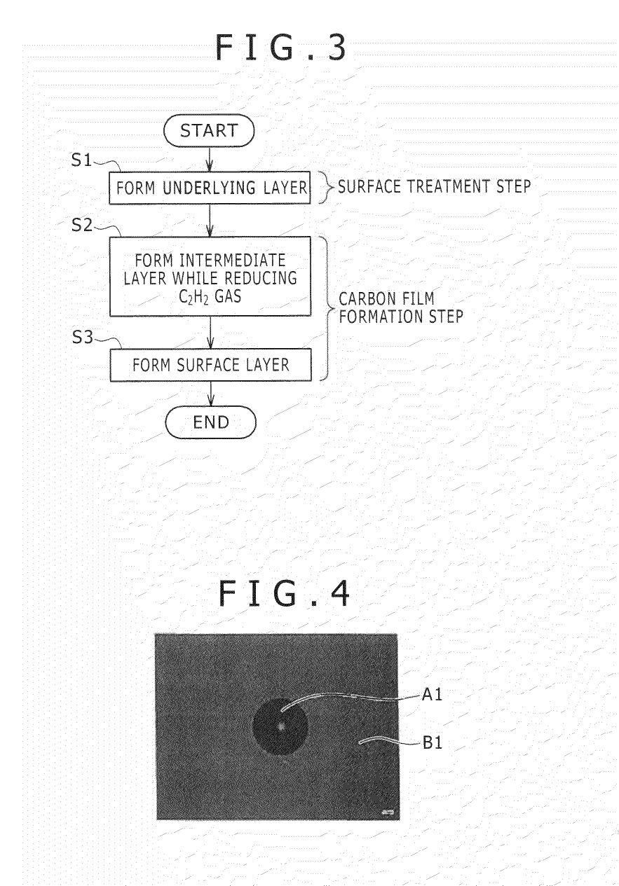

Manufacture of the hard sliding member 20 with using the film deposition device 1 constructed as above is performed for example in the order shown in the flowchart of FIG. 3. Specifically, see the following.

Firstly, the works W serving as the substrate 21 of the hard sliding member 20 (for example, cemented carbide test pieces made of mirror-finished tungsten carbide) are mounted on the rotation table 3, and the surface treatment step of the substrate 21 is performed.

As the surface treatment step, firstly, a bombardment treatment of the substrate 21 is performed. The air inside the space portion 2a of the vacuum chamber 2 is discharged to the exterior of the chamber by the vacuum pump (not shown), so as to obtain a vacuum degree of about 5×10⁻³ Pa. A heater 11 is held for 30 minutes in a state where the air inside the space portion 2a is heated at 400° C.

Next, an inert gas of argon or the like at pressure of 1.33 Pa is supplied into the space portion 2a of the vacuum chamber 2 from the introduction portion 6, and argon plasma is generated by thermal electrons from an electron source (not shown). In this state, the rotation table 3 is rotated in a state where the works W are mounted on the rotation table 3. Next, by applying bias voltage −300 V to the works W by a bias power source 10 via the rotation table 3 and colliding argon ions in the argon plasma with the works W, the bombardment treatment of thinly grinding the surfaces of the works W is performed. By this bombardment treatment, foreign substances on the surfaces of the works W are removed, and minute unevenness is generated on the surfaces of the works W, so that adhesion force can be improved by activation of the surfaces of the works W.

After performing the bombardment treatment, firstly, by the AIP with using the first arc evaporation sources 4, the underlying layer 22 made of chromium (Cr) is formed on the surfaces of the works W (that is, the substrate 21) (refer to Step S1 of the flowchart of FIG. 3). Specifically, the inert gas of argon or the like is supplied into the space portion 2a of the vacuum chamber 2 from the introduction portion 6 so that pressure inside the chamber 2 becomes pressure of substantially 1.0 Pa (the inert gas is charged at a flow rate of 1,000 ml/min). Together, a high electric current is applied to the first arc evaporation sources 4 from the arc power sources 8, so that bias voltage of −40 V is given to the works W. At this time, the arc discharge is generated between the chromium targets 12 of the first arc evaporation sources 4 and the anodes. By this arc discharge, part of the targets 12 is melt, evaporated, and metal-ionized at a larger rate and attached to the works W. At this time, the underlying layer 22 made of pure chromium is formed on the surfaces of the works W. Formation of the underlying layer 22 is performed for 5 minutes, and the underlying layer 22 having thickness of 0.05 μm is obtained. As the underlying layer 22, in addition to pure chromium, chromium nitride (CrN) generated by adding nitride in place of argon may be used. Chromium ions may be used as metal bombardment of pulling the chromium ions by bias voltage of −1,000 V to the works W for example.

Next, by the AIP with using the second arc evaporation sources 5, the carbon film 23 including the intermediate layer 24 and the surface layer 25 is formed on the underlying layer 22 of the works W.

Specifically, before an end of film deposition of the underlying layer 22 made of chromium, specifically, from a latter part of the film deposition step of the underlying layer 22, while the arc discharge is generated in the chromium targets 12, the hydrocarbon gas made of acethylene (C₂H₂) is added to argon at a flow rate (introduction amount) of 130 ml/min and charged into the chamber 2, and the arc discharge is generated in the carbon (C) targets 13, so that formation of the intermediate layer 24 of the carbon film 23 is started by the AIP.

In such a way, by starting the carbon film formation step while introducing the hydrocarbon gas immediately before the end of the step of generating the underlying layer 22, a hardness difference in a border part between the underlying layer 22 and the carbon film 23 is more reduced (in other words, more uniformized). Thereby, an adhesion property of the underlying layer 22 and the carbon film 23 is more improved.

While the introduction amount of the hydrocarbon gas is gradually reduced from 130 ml/min to 20 ml/min over 5 minutes, the arc discharge is generated in the carbon (C) targets 13, and the intermediate layer 24 made of soft DLC is formed as the intermediate layer 24 of the carbon film 23 (Step S2 of FIG. 3). In such a way, by gradually reducing the introduction amount of the hydrocarbon gas, the hardness and the internal stress of the intermediate layer 24 to be formed can be improved. Further, by gradually lowering negative bias voltage to be given to the works W (that is, gradually increasing to the minus side) in accordance with reduction in the introduction amount of the hydrocarbon gas, improvement of the hardness and the internal stress of the intermediate layer 24 to be formed can be assisted (that is, aided or helped).

Next, in a state where the introduction of the hydrocarbon gas is stopped, the arc discharge is generated in the carbon (C) targets 13, and the surface layer 25 made of ta-C is formed by the AIP (Step S3 of FIG. 3). In an initial stage of formation of the surface layer 25, by adjusting the introduction amount of the hydrocarbon gas to be gradually reduced from 20 ml/min to 0 ml/min, a hardness difference in a border part between the intermediate layer 24 and the surface layer 25 is more reduced.

As described above, by successively forming the underlying layer 22 and the carbon film 23 (the intermediate layer 24 and the surface layer 25) by the AIP, the hard sliding member 20 having the underlying layer 22 and the carbon film 23 shown in FIG. 1 can be manufactured.

In the hard sliding member 20 manufactured by the manufacturing method of the present embodiment as described above, the carbon film 23 formed on the underlying layer 22 has the intermediate layer 24 made of soft DLC, and the surface layer 25 made of ta-C. Furthermore, since the intermediate layer 24 is formed by the AIP while reducing the introduction amount of the hydrocarbon gas, the intermediate layer has the structure in which the hydrogen content is gradually reduced as distant from the underlying layer 22 in the intermediate layer. Therefore, the part of the intermediate layer 24 near the underlying layer 22 has low hardness, and the part near the surface layer 25 has high hardness. Thereby, the hardness difference between the underlying layer 22 and the intermediate layer 24 can be reduced, and the hardness difference between the intermediate layer 24 and the surface layer 25 can also be reduced. Thereby, separation of the hard carbon film 23 containing ta-C from the substrate 21 can be prevented.

Therefore, regarding the hard sliding member 20 manufactured by the manufacturing method of the present embodiment, as shown in FIG. 4, when a Rockwell impression test of pressing a conical indenter onto the surface of the hard sliding member and examining impressions were performed, an impression A1 was formed on a surface B1 by the indenter but a separating part of the carbon film 23 was not found.

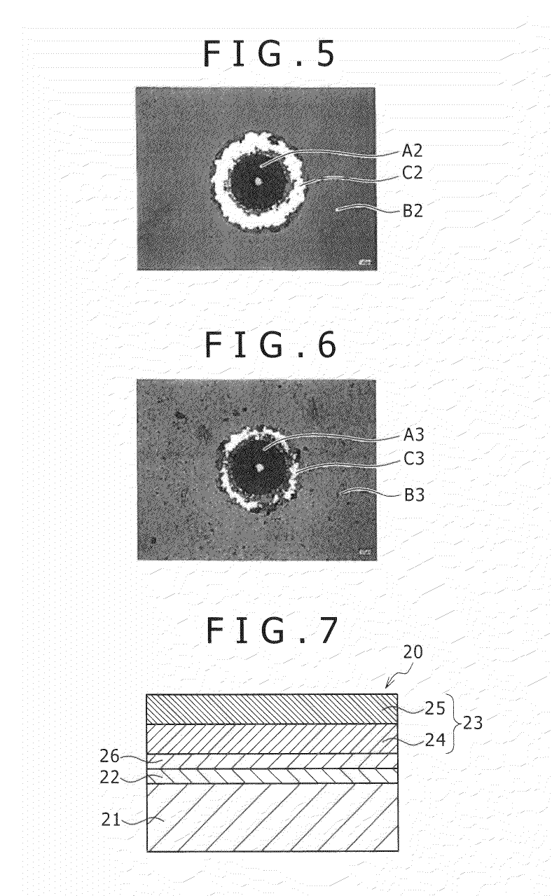

As a comparative example, regarding a case where a hard sliding member is manufactured by forming a surface layer made of ta-C directly on an underlying layer made of chromium by the AIP, the same Rockwell impression test was performed to the member. In a result of the test, as shown in FIG. 5, a separating part C2 of the surface layer was found around an impression A2 formed on a surface B2.

As another comparative example, regarding a case where a hard sliding member is manufactured by changing bias voltage to works from −20 V to −50 V in an initial stage of formation of a surface layer at the time of forming the surface layer made of ta-C directly on a underlying layer made of chromium by the AIP, the same Rockwell impression test was performed. In a result of the test, as shown in FIG. 6, a separating part C3 of the surface layer was also found around an impression A3 formed on a surface B3.

Therefore, unlike these comparative examples shown in FIGS. 5 to 6, in the hard sliding member manufactured as in the present embodiment, even when the same Rockwell impression test is performed, no separation of the hard carbon film 23 containing ta-C is generated as shown in FIG. 4. Thus, it is found that the adhesion property of the carbon film 23 is improved.

The manufacturing method of the hard sliding member of the present invention is described above with the embodiment. However, the present invention is not limited to this but the following modified example is included in the present invention.

That is, in the above embodiment, the carbon film 23 is formed directly on the underlying layer 22. However, the present invention is not limited to this but an interposition layer 26 may be formed between the underlying layer 22 and the carbon film 23. For example, as a modified example of the present invention, as shown in FIG. 7, the surface treatment step may further include an interposition layer formation step of forming the interposition layer 26 having higher hardness than that of the underlying layer 22 and lower hardness than that of the carbon film 23 (specifically, the intermediate layer 24) on the underlying layer 22 by the AIP. In this case, since the interposition layer 26 having the hardness in the middle of the hardness of the underlying layer 22 and the hardness of the carbon film 23 is formed on the underlying layer 22 by the AIP, the hardness difference and the internal stress difference between the carbon film 23 (specifically, the intermediate layer 24) and the underlying layer 22 can be further reduced. Furthermore, the underlying layer 22, the interposition layer 26, and the carbon film 23 can be continuously formed by the AIP process, so that the adhesion property is improved.

In the above embodiment, as the surface treatment step, the underlying layer 22 is formed on the surface of the substrate 21. However, the present invention is not limited to this but other surface treatments may be performed instead of formation of the underlying layer 22. For example, as the surface treatment step, a step of treating the surface of the substrate 21 by metal bombardment may be performed. The metal bombardment may be performed for example by colliding chromium ions emitted from the targets 12 made of chromium with the surface of the substrate 21. In this case, by reforming the surface of the substrate 21 itself by the metal bombardment, the adhesion property with the carbon film 23 can be improved. Furthermore, there is a low likelihood that the surface of the substrate 21 treated by the metal bombardment separates from the substrate 21 like the underlying layer 22.

What is claimed is:

1. A manufacturing method of a hard sliding member including a substrate, and a carbon film formed on a surface of the substrate, the carbon film having higher hardness than hardness of the substrate, the manufacturing method comprising:
a surface treatment step of surface-treating the surface of the substrate; and
a carbon film formation step of forming the carbon film on the surface of the substrate by performing arc ion plating in a chamber with using a target containing carbon, wherein
in said carbon film formation step, formation of the carbon film is started by performing the arc ion plating while introducing a hydrocarbon gas into the chamber, and then an introduction amount of the hydrocarbon gas into the chamber is reduced and the arc ion plating is continued, so that ta-C is formed at least on a surface.

2. The manufacturing method of the hard sliding member according to claim 1, wherein
said carbon film formation step includes:
a step of performing the arc ion plating with using the target containing carbon while introducing the hydrocarbon gas in such a manner that the introduction amount of the hydrocarbon gas into the chamber is gradually reduced over time.

3. The manufacturing method of the hard sliding member according to claim 1, wherein
said carbon film formation step includes:
a step of forming a surface layer containing ta-C by continuing the arc ion plating with using the target containing carbon even after stopping introduction of the hydrocarbon gas.

4. The manufacturing method of the hard sliding member according to claim 1, wherein
the hydrocarbon gas is acethylene.

5. The manufacturing method of the hard sliding member according to claim 1, wherein
the hydrocarbon gas is methane.

6. The manufacturing method of the hard sliding member according to claim 1, wherein
said surface treatment step includes:
a step of forming an underlying layer on the substrate by the arc ion plating.

7. The manufacturing method of the hard sliding member according to claim 6, wherein
said carbon film formation step is started while introducing the hydrocarbon gas immediately before an end of said step of forming the underlying layer.

8. The manufacturing method of the hard sliding member according to claim 6, wherein
said surface treatment step further includes:
an interposition layer formation step of forming an interposition layer having higher hardness than that of the underlying layer and lower hardness than that of the carbon film on the underlying layer by the arc ion plating.

9. The manufacturing method of the hard sliding member according to claim 1, wherein
said surface treatment step is a step of treating the surface of the substrate by metal bombardment.
